(19) United States
(12) Patent Application Publication
(10) Pub. No.: US 2016/0286671 A1
(43) Pub. Date: Sep. 29, 2016

(54) PORTABLE ELECTRONIC DEVICE WITH COVER GLASS PROTECTION

(71) Applicant: CORNING INCORPORATED, CORNING, NY (US)

(72) Inventors: lzhar Zahoor Ahmed, Painted Post, NY (US); Petr Gorelchenko, Roshino (RU); Guangli Hu, Berkeley Heights, NJ (US); Po-Jen Shih, Webster, NY (US); Irene Marjorie Slater, Lindley, NY (US); Vijay Subramanian, Painted Post, NY (US); Bin Zhang, Penfield, NY (US); Sam Samer Zoubi, Horseheads, NY (US)

(21) Appl. No.: 15/078,202

(22) Filed: Mar. 23, 2016

Related U.S. Application Data
(60) Provisional application No. 62/139,247, filed on Mar. 27, 2015.

(51) Int. Cl. H05K 5/02; H05K 5/00; H05K 5/03

(52) U.S. Cl. CPC H05K 5/0217; H05K 5/03; H05K 5/0017

(57) ABSTRACT

A portable electronic device includes a device body containing a plurality of device structures, one of which is a display module. A cover glass is disposed at an opening of the device body such that at least one of the plurality of device structures underlies the cover glass. An energy absorbing interlayer is disposed between the cover glass and the at least one underlying device structure, where the energy absorbing interlayer has a stiffness that is lower than that of the cover glass.

### CROSS-REFERENCE TO RELATED APPLICATIONS

This application claims the benefit of priority under 35 U.S.C. §119 of U.S. Provisional Application Ser. No. 62/139,247 filed on Mar. 27, 2015, the content of which is relied upon and incorporated herein by reference in its entirety.

### BACKGROUND

The mobile nature of portable devices, such as smartphones, tablets, portable media players, personal computers, and cameras, makes these devices particularly vulnerable to accidental dropping on hard surfaces, such as the ground. These devices typically incorporate cover glasses, which may become damaged upon impact with hard surfaces. In many of these devices, the cover glasses function as display covers, and may incorporate touch functionality, such that use of the devices is negatively impacted when the cover glasses are damaged.

There are two major failure modes of cover glass when the associated portable device is dropped on a hard surface. One of the modes is flexure failure, which is caused by bending of the glass when the device is subjected to dynamic load from impact with the hard surface. The other mode is sharp contact failure, which is caused by introduction of damage to the glass surface. Impact of the glass with rough hard surfaces, such as asphalt, granite, etc., can result in sharp indentations in the glass surface. These indentations become failure sites in the glass surface from which cracks may develop and propagate.

Glass can be made more resistant to flexure failure by ion-exchange technique, which involves inducing compressive stress in the glass surface. However, the ion-exchanged glass will still be vulnerable to dynamic sharp contact, owing to the high stress concentration caused by local indentations in the glass from the sharp contact.

It has been a continuous effort for the glass makers and handheld device manufacturers to improve the resistance of handheld devices to sharp contact failure. Solutions range from coatings on the cover glass to bezels that prevent the cover glass from touching the hard surface directly when the device drops on the hard surface. However, due to the constraints of aesthetic and functional requirements, it is very difficult to completely prevent the cover glass from touching the hard surface.

### SUMMARY

The invention relates to a method of reducing damage to the cover glass of a portable electronic device due to impact of the device on a hard surface.

In one illustrative embodiment, a portable electronic device includes a device body having a cavity in which a plurality of device structures is contained, one of the device structures being a display module. A cover glass is disposed at an opening of the device body such that at least one of the plurality of device structures underlies the cover glass. An energy absorbing interlayer is disposed between the cover glass and the at least one underlying device structure. The energy absorbing interlayer has a stiffness that is lower than a stiffness of the cover glass.

In another illustrative embodiment, a cover glass article for a portable electronic device includes a cover glass shaped to at least partially cover an opening of a device body of the portable electronic device. The cover glass is made of a glass or glass-ceramic material having at least one surface under a compressive stress of at least 200 MPa and a compressively stressed layer with a depth of layer of at least 1% of a thickness of the material. An energy absorbing layer is formed on a surface of the cover glass. The energy absorbing layer has a stiffness lower than a stiffness of the cover glass.

It is to be understood that both the foregoing general description and the following detailed description are exemplary of the invention and are intended to provide an overview or framework for understanding the nature and character of the invention as it is claimed. The accompanying drawings are included to provide a further understanding of the invention and are incorporated in and constitute a part of this specification. The drawings illustrate various embodiments of the invention and together with the description serve to explain the principles and operation of the invention.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

FIG. 1A is a diagram of a portable electronic device incorporating an energy absorbing interlayer between a cover glass and underlying device structures.

FIG. 1B shows the energy absorbing interlayer of FIG. 1A with non-uniform thickness.

FIG. 1C is a diagram of a portable electronic device incorporating an energy absorbing interlayer between a cover glass and a bezel.

FIG. 2A shows an energy absorbing interlayer as a solid sheet of material.

FIG. 2B shows an energy absorbing interlayer as a perforated sheet of material.

FIG. 2C shows an energy absorbing interlayer as strips of material.

FIG. 2D shows an energy absorbing interlayer as criss-crossed strips of material.

FIG. 2E shows an energy absorbing interlayer as a loop shape.

FIGS. 3A and 3B show an energy absorbing interlayer with thicker corner areas.

FIGS. 3C and 3D show an energy absorbing interlayer with thicker edge areas.

FIG. 4 is a diagram of a spring model for the portable electronic device incorporating an energy absorbing interlayer.

FIG. 5 is a plot showing maximum principal stress under indentation as a function of indentation contact force on a glass surface.

FIG. 6A is a test model for a portable electronic device incorporating an energy absorbing interlayer.

FIG. 6B shows a test model in contact with a hard surface.

FIG. 7 is a plot showing contact force as a function of time in a drop event simulation using the test model.

FIG. 8 is a plot showing dependency of contact force on modulus and thickness of the soft interlayer in drop events.

### DETAILED DESCRIPTION

A method of protecting a cover glass on a portable device, particularly of the handheld type, from damage when the device falls on a hard surface, such as the ground, involves disposing a thin energy absorbing interlayer between the cover glass and underlying device structures. The energy absorbing interlayer will increase the resistance of the cover glass to sharp contact failure due to impact of the device with the hard surface. According to simulation studies of handheld devices, the interlayer material underneath the cover glass plays an important role in the dynamic contact force between the cover glass and the hard surface, which is believed to be strongly related to glass damage due to dynamic sharp indentation. It has been observed that the lower the stiffness of the energy absorbing interlayer is, the lower the contact force between the cover glass and the hard surface, thus the lower the probability of glass failure under sharp indentation. Therefore, within the design space of the handheld device system, reducing the rigidity of the interlayer material underneath the cover glass will reduce the glass damage.

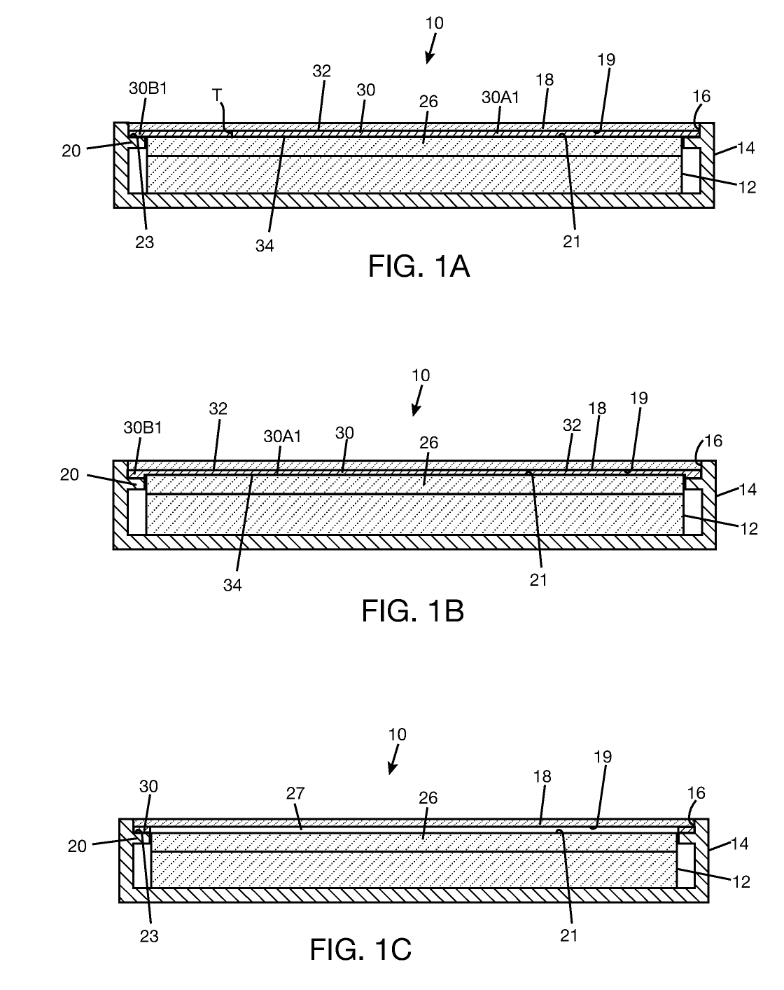

FIG. 1A shows a portable electronic device 10 according to one embodiment. The portable electronic device 10 may be a consumer portable, including handhelds and wearables, such as a smartphone, tablet, portable media player, smart watch, and the like. The portable electronic device 10 includes a device body 14 having a front opening 16 in which a cover glass 18 is disposed. The cover glass 18 may be attached, or coupled, to the device body 14 by any suitable means, such as by a bezel 20, which may be an integral part of the device body 14 or may be attached, or otherwise coupled, to the device body 14. The portable electronic device 10 further includes an electronic device unit 12, which includes various components necessary for operation and use of the portable electronic device 10. In one embodiment, the electronic device unit 12 includes a display module 26, which may be positioned underneath the cover glass 18 as shown in FIG. 1. In one embodiment, the display module 26 may be a touch-sensitive display. In one embodiment, the cover glass 18 may incorporate touch functionality. This means that the cover glass 18 can detect touch. In one example, the touch functionality may be based on a coating system that is deposited on the underside of the cover glass 18 and that incorporates touch sensors. In another example, the touch functionality may be based on an optical method that uses sensors disposed on the edges of the cover glass 18. The electronic device unit 12 may include other components such as processor or controller, memory, battery, camera, speaker, microphone, and the like—these components are known in the art and will not be shown or discussed individually herein. The electronic device unit 12 is disposed in a cavity 13 of the device body 14, generally underneath the cover glass 18. Some of the components of the electronic device unit 12 may be attached to the device body 14 or to a frame or bracket (not shown separately) inside the device body cavity 13 or to the bezel 20.

In one embodiment, the cover glass 18 is made of a glass or glass-ceramic material. In one embodiment, for improved resistance to scratching and flexure failure, the cover glass 18 may preferably be made of a glass or glass-ceramic material that has been chemically strengthened. In one embodiment, the cover glass 18 may be made of a glass or glass-ceramic material that has been chemically strengthened to have at least one surface under a compressive stress of at least 200 MPa and a compressively stressed layer with a depth of layer (DOL) of at least 1% of the material thickness. In another embodiment, the cover glass 18 may be made of a glass or glass-ceramic material that has been chemically strengthened to have at least one surface under a compressive stress of at least 700 MPa and a compressively stressed layer with a DOL of at least 1% of the material thickness. GORILLA® glass, available from Corning Incorporated, New York, is an example of a class of glasses that may be used for the cover glass 18. Other materials suitable for making the cover glass 18 may be hard plastics or ceramics.

The cover glass 18 may have a 2D or 3D shape, such as flat shape, dish shape, or sled shape, adapted for at least partially covering the front opening 16 of the device body 14. In one embodiment, the cover glass 18 may be transparent to allow viewing of the images processed by the underlying display module 26. Typically, the cover glass 18 will have a uniform thickness. For portable electronic devices where thinness is typically important, the thickness of the cover glass 18 may be between 50 microns and 2.0 mm.

In one embodiment, the portable electronic device 10 further includes one or more energy absorbing interlayers disposed between the cover glass 18 and selected underlying device structures. The particular underlying device structures will depend on the configuration or design of the portable electronic device 10. The energy absorbing interlayer(s) will absorb impact energy from the cover glass 18 during a drop event, thereby protecting the cover glass 18 from damage.

In one embodiment, as shown in FIG. 1A, a portion 30A1 of an energy absorbing layer 30 is disposed between the back surface 19 of the cover glass 18 and the front surface 21 of the display module 26. Also, a portion 30B1 of the energy absorbing interlayer 30 is disposed between the back surface 19 of the cover glass 18 and a mounting surface 23 of the bezel 20. In this case, the bezel 20 and display module 26 are examples of underlying device structures.

The energy absorbing interlayer portions 30A1, 30B1 may have the same or different energy absorbing characteristics. FIG. 1B shows portion 30B1 with a different thickness than portion 30A1, for example, which may result in these portions having different energy absorbing characteristics. Also, it is possible to provide the portions 30A1, 30B1 as separate (unconnected) energy absorbing interlayers whose energy absorbing characteristics can be tailored to the corresponding part of the cover glass 18. FIG. 1C shows another example where the energy absorbing interlayer 30 is disposed only between the cover glass 18 and the bezel 20. In this example, there may be an air gap 27 between the cover glass 18 and the display module 26.

In some embodiments, it may be convenient to use the back surface 19 of the cover glass 18 as a carrier for the energy absorbing interlayer 30. That is, the energy absorbing interlayer 30 may be formed on, or applied to, the back surface 19 of the cover glass 18 such that when the cover glass 18 is disposed at the front opening 16 of the device body 14, the energy absorbing interlayer 30 will be in the appropriate position between the cover glass 18 and the desired underlying device structure(s).

Each energy absorbing interlayer 30 is sandwiched between the cover glass 18 and one or more device structures underlying the cover glass 18, i.e., underlying device structure(s). In one embodiment, the energy absorbing interlayer 30 is “soft” relative to the adjacent cover glass 18. The energy absorbing interlayer 30 is preferably also soft relative to each adjacent underlying device structure. Stiffness may be used as a measure of softness. Therefore, the energy absorbing layer 30 may be considered as softer than a part if it has a stiffness that is lower than that of the part. Also, Young's modulus, or elastic modulus, may provide a measure of stiffness. Therefore, the energy absorbing layer 30 may be considered as softer than a part if it has a Young's modulus that is smaller than that of the part. In one embodiment, the energy absorbing interlayer 30 has a Young's modulus that is at least 10 times smaller than the Young's modulus of the cover glass 18. In another embodiment, the energy absorbing interlayer 30 has a Young's modulus that is at least 50 times smaller than the stiffness of the cover glass 18. In yet another embodiment, the energy absorbing interlayer 30 has a Young's modulus that is at least 100 times smaller than the stiffness of the cover glass 18.

The underlying device structure adjacent to the energy absorbing interlayer 30 may be a composite structure made of many different parts and materials. This is the case, for example, if the underlying device structure is a display module. In this case, determining the modulus of the underlying device structure may not be a simple matter. However, if the modulus of the energy absorbing interlayer 30 is several times smaller than the modulus of the cover glass 18, for example, 10 or more times smaller than the modulus of the cover glass 18, it may be assumed that the energy absorbing interlayer 30 will most likely be softer than the adjacent underlying device structure. Drop tests can be used to ascertain that an energy absorbing interlayer 30 having a particular Young's modulus will provide the desired impact energy absorption when used in a portable electronic device of a particular configuration.

There are ISTM standards for determining the elastic modulus of layered composites, such as D790 Test Methods for Flexural Properties of Unreinforced and Reinforced Plastics and Electrical Insulating Materials; D3039/D3039M Test Method for Tensile Properties of Polymer Matrix Composite Materials; D3410/D3410M Test Method for Compressive Properties of Polymer Matrix Composite Materials with Unsupported Gage Section by Shear Loading; D3518/D3518M Test Method for In-Plane Shear Response of Polymer Matrix Composite Materials by Tensile Test of a 45 Laminate; D3552 Test Method for Tensile Properties of Fiber Reinforced Metal Matrix Composites; D5379/D5379M Test Method for Shear Properties of Composite Materials by the V-Notched Beam Method; E6 Terminology Relating to Methods of Mechanical Testing; E111 Test Method for Young's Modulus, Tangent Modulus, and Chord Modulus. Any appropriate one of these standards may be used to determine the modulus of the display module 26 and other composite underlying device structures if it is desired to verify that the energy absorbing interlayer 30 is softer than the adjacent underlying device structure.

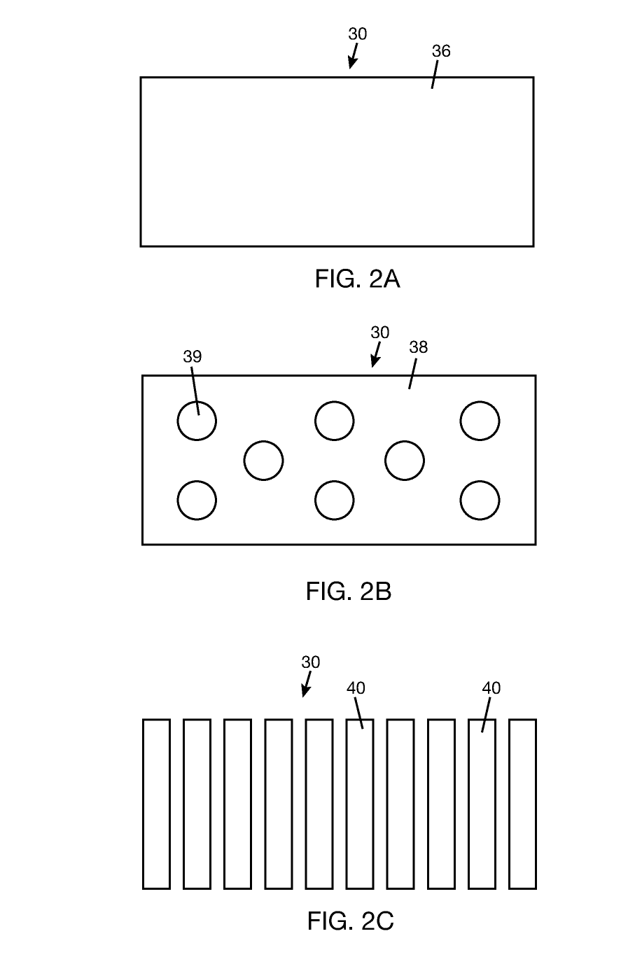

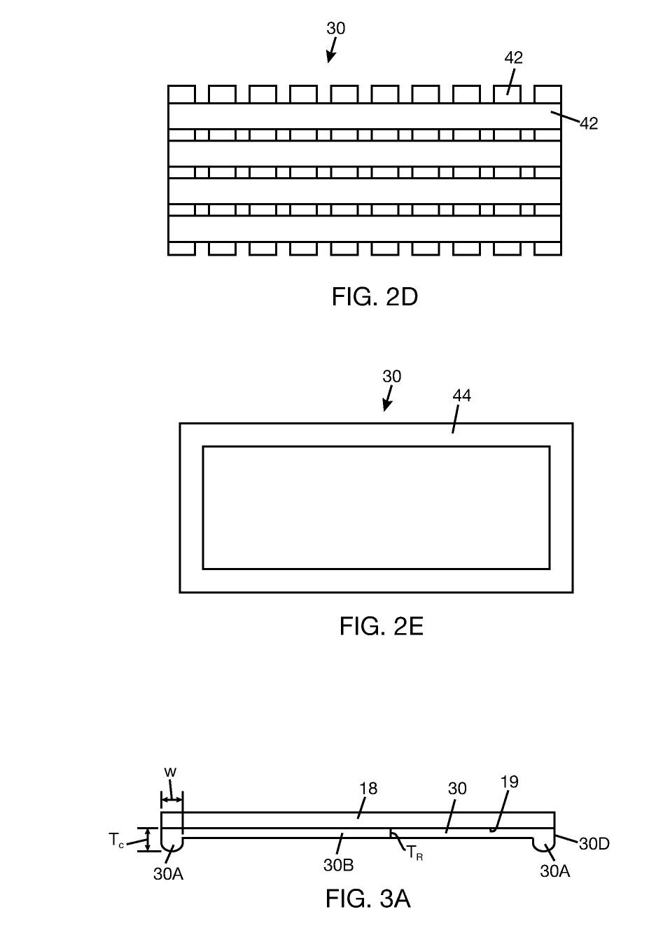

The energy absorbing interlayer 30 can have a variety of geometries when viewed from its front surface 32 (or its back surface 34). In one example, the energy absorbing interlayer 30 may be in the form of a sheet extending across the back surface 19 of the cover glass 18. FIG. 2A shows an example of the energy absorbing interlayer 30 as a solid sheet 36. FIG. 2B shows an example of the energy absorbing interlayer 30 as a perforated sheet 38 having holes 39. In another example, the energy absorbing interlayer 30 may be in the form of strips arranged in a layer, as shown at 40 and 42 in FIGS. 2C and 2D, respectively. In yet another example, the energy absorbing interlayer 30 may be in the form of a loop, as shown at 44 in FIG. 2E. Other geometries of the energy absorbing interlayer 30 besides those mentioned above are possible. In general, the energy absorbing interlayer 30 may be a solid layer of material or a layer of material having one or more holes or spaces. The energy absorbing interlayer 30 should be transparent if it overlaps the display area of a display (as shown in FIGS. 1A and 1B for the display module 26). This will allow viewing of the images processed through the transparent cover glass 18 and energy absorbing interlayer 30. If the energy absorbing interlayer 30 is provided in a loop shape such that it does not cover the display area of a display (as shown in FIG. 1C), then it may be not be necessary for the energy absorbing interlayer 30 to be transparent.

The geometric definition of the energy absorbing interlayer 30 also includes the layer thickness (T in FIG. 1A) of the energy absorbing interlayer 30. The energy absorbing interlayer 30 may have a uniform layer thickness, as shown in FIGS. 1A and 1C, or may have a non-uniform thickness, as shown in FIG. 1B. Studies have shown that the corners and edges of a cover glass are at higher risk for damage during a drop event compared to the central region of the cover glass. The energy absorbing interlayer 30 may be selected to be relatively thick in the corner and/or edge areas and relatively thin (down to a thickness of zero in the case of a loop shape) in the central area. The thicker corner and/or edge areas will provide added protection in the high risk areas of the cover glass, while the thinner central area will allow the energy absorbing interlayer to maintain a relatively thin profile within the electronic device.

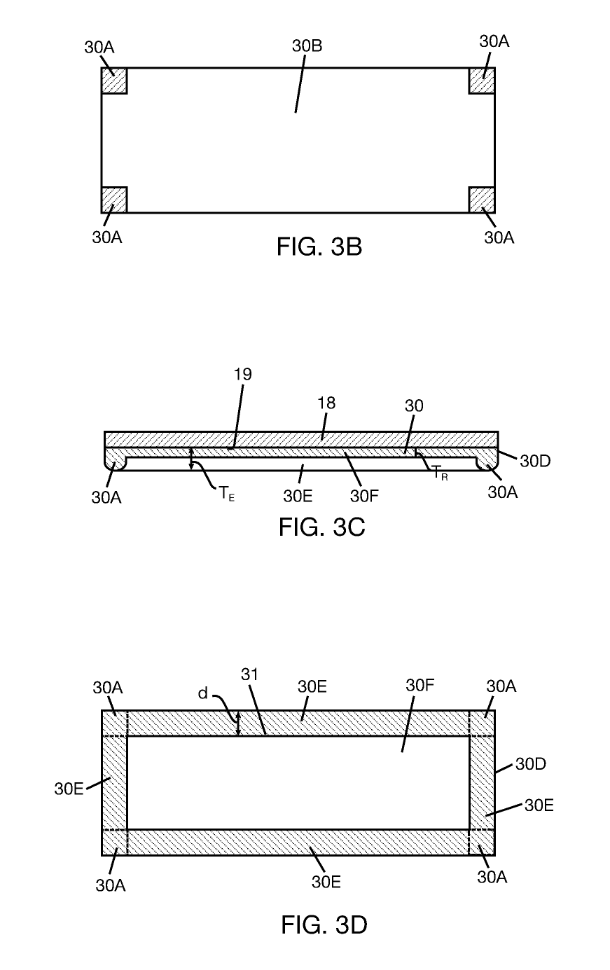

FIGS. 3A and 3B show an example where the corner areas 30A of the energy absorbing interlayer 30 are thicker than the remaining area (non-corner area) 30B of the energy absorbing interlayer 30. In one embodiment, the corner areas 30A may be located within 5 mm of the periphery 30D of the energy absorbing interlayer 30, i.e., the dimension w in FIG. 3A can be up to 5 mm. The sizing of the energy absorbing interlayer 30 may be such that the corner areas 30A of the energy absorbing interlayer 30 will correspond to the corners of the cover glass 18 when the energy absorbing interlayer 30 is adjacent to the back surface 19 of the cover glass 18 as shown in FIG. 3A, thereby providing added protection to the corners of the cover glass 18. In one embodiment, the ratio of the thickness of each of the corner areas 30A (T_{c}) to the thickness of the remaining area 30B (T_{R}) is 1.5 or greater. In another embodiment, the ratio of the thickness of each of the corner areas 30A (T_{c}) to the thickness of the remaining area 30B (T_{R}) is 2.0 or greater.

FIGS. 3C and 3D show an example where the edge areas 30E of the energy absorbing interlayer 30 are thicker than the remaining area (non-edge area) 30F of the energy absorbing interlayer 30. The edge areas 30E encompass the areas along the periphery 30D of the energy absorbing interlayer 30, including the corner areas 30A. In one embodiment, the edge areas 30E may be located within 5 mm of the periphery 30D of the energy absorbing interlayer 30, i.e., the distance d between the periphery 30D and inner boundary 31 of the edge areas 30E can be up to 5 mm. The sizing of the energy absorbing interlayer 30 may be such that the edge areas 30E of the energy absorbing interlayer 30 will correspond to the edge areas of the cover glass 18 when the energy absorbing interlayer 30 is adjacent to the back surface 19 of the cover glass 18 as shown in FIG. 3C. In one embodiment, the ratio of thickness of each of the edge areas 30E (T_{E}) to the thickness of the remaining area 30F (T_{R}) is 1.5 or greater. In another embodiment, the ratio of the thickness of each of the edge areas 30E (T_{E}) to the thickness of the remaining area 30F (T_{R}) is 2.0 or greater.

Stiffness is a structural property influenced by the geometry of the structure and the materials used in the structure. The material and thickness of the energy absorbing interlayer 30 can be selected such that the energy absorbing interlayer 30 has a lower stiffness compared to the stiffness of the cover glass 18. The stiffness of a material is the extent to which the material can resist deformation in response to an applied force. The softer a material is, the less the material will be able to resist deformation in response to an applied force. Young's (or elastic) modulus provides a measure of the stiffness of an elastic material. In one embodiment, the material used in the energy absorbing interlayer 30 may have a Young's modulus selected from <20 GPa, <10 GPa, <1 GPa, <100 MPa, <1 MPa, and <0.1 MPa. In one embodiment, the layer thickness T of the energy absorbing interlayer 30 may be selected from >50 nm, >100 nm, >500 nm, >1 μm, >5 μm, >10 μm, >100 μm, >1 mm, and >5 mm. In general, the softer and thicker the energy absorbing interlayer 30, the better the reduction in contact force under drop. However, there are practical limits to the thickness of the energy absorbing interlayer 30 based on design specification of the device, such as user touch experience and overall thickness of the device. In one example, the energy absorbing interlayer 30 may have a Young's modulus in a range from 1 MPa to 100 MPa and a layer thickness in a range from 100 μm to 2.5 mm, where the the layer thickness could be uniform or non-uniform.

In one embodiment, the energy absorbing interlayer 30 is made of one or more polymers. The polymer(s) may be deposited as a film on the back surface 19 of the cover glass 18 using any suitable film deposition or coating process. Alternatively, the polymer may be provided as a separate element that can be disposed between the cover glass 18 and underlying device structure(s) of interest. Optically clear adhesive (OCA) is one example of a polymer product that can be used to form the energy absorbing interlayer 30. There are two types of OCA: liquid optically clear adhesive and optically clear adhesive made as a double-sided tape. One commercial example of liquid OCA is Printable Liquid Optically Clear Adhesive 1088 from 3M Company. The liquid OCA can be deposited on the back surface 19 of the cover glass 18 and then cured using, for example, UV radiation, to form the energy absorbing interlayer 30 on the back surface 19 of the cover glass 18. Commercial examples of OCA tapes are 3M Optically Clear Adhesive 821X and 9483AS from 3M Company. These OCAs are made of acrylic. The OCA tape can be applied to the back surface 19 of the cover glass 18. However, an additional process, such as autoclave, may be needed to remove any bubbles in the resulting energy absorbing layer 30. When used in the display area, the OCA will have the advantage of maintaining the optical performance of the display module 26. Other examples of materials that may be used in the energy absorbing interlayer 30 are foam materials and rubber or elastomer materials.

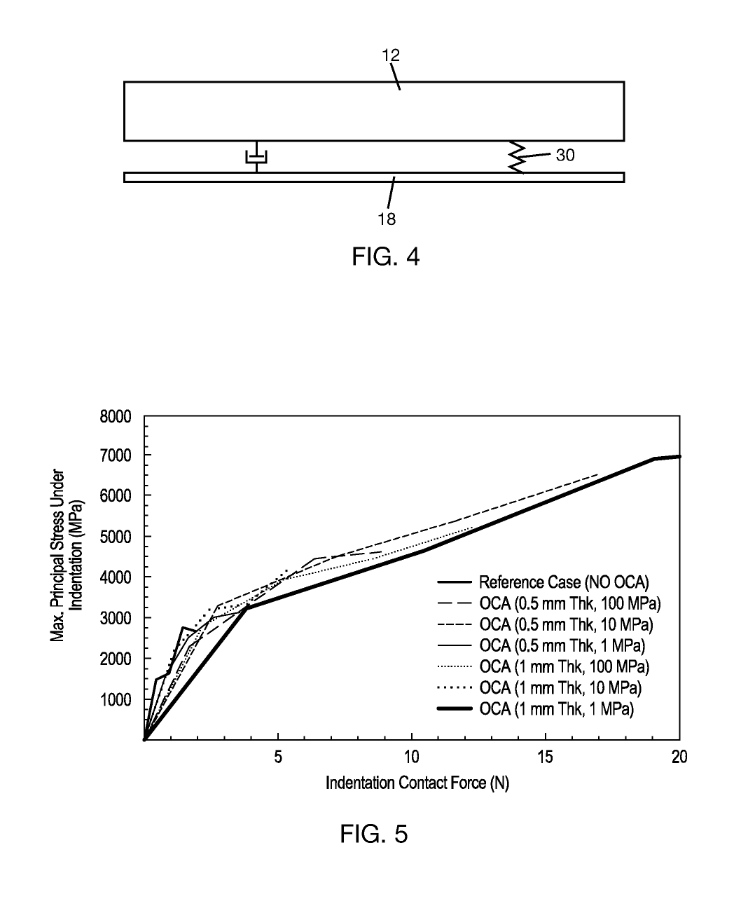

When the cover glass 18 hits a hard surface during a device drop event, the energy absorbing interlayer 30 will respond like a spring and dashpot system, dampening the impact of the contact force on the cover glass 18. FIG. 4 shows a spring and dashpot model of the energy absorbing interlayer 30 between the cover glass 18 and the electronic device unit 12. Assume that the mass of the portable electronic device 10 is m, the velocity of the electronic device 10 at the moment of contact with a hard surface is v, the spring constant of the interlayer is k, and the maximum spring compression is x, then the energy conservation equation of the system is:

$$\frac{{mv}^{2}}{2} = \frac{{kx}^{2}}{2} \qquad ( 1 )$$

Solving for x in Equation (1) yields:

$$x = v \cdot \sqrt{\frac{m}{k}} \qquad ( 2 )$$

From Equation (2), softer springs (lower k) result in larger spring compression (larger x). This means that the electronic device 10 needs to travel a longer distance to come to a full stop before springing back. For the electronic device 10 with the same initial velocity, longer travel time means lower deceleration. According to Newton's second law (F=ma), lower a (acceleration) results in lower F (force). Here, F is the reaction force between the cover glass 18 and the hard surface. This provides a basis for the theory that using an energy absorbing interlayer 30 between the cover glass 18 and underlying device structure(s) will reduce the probability of cover glass damage due to sharp indentation.

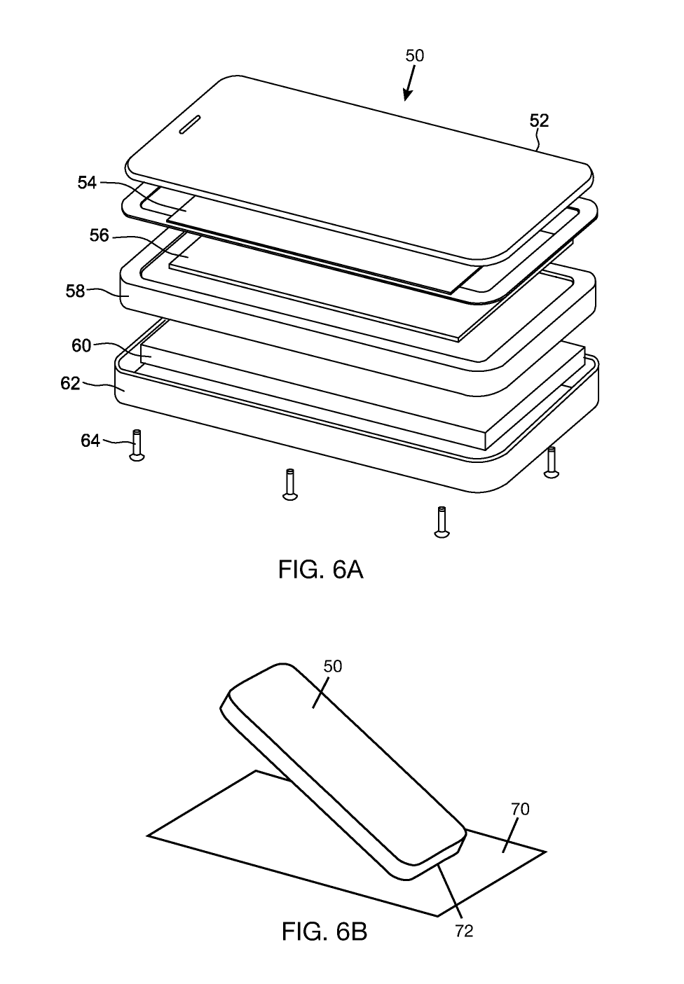

A glass reliability performance study was conducted to demonstrate the above theory. Before the study was conducted, a decision had to be made about the criteria to use in comparing glass reliability performance. For this purpose, a static indentation study was conducted in which a sharp indenter was pushed against a glass surface. FIG. 5 shows a plot of glass stress versus contact force obtained from the static indentation study. FIG. 5 shows results for seven samples. One of the samples was a reference case without an optically clear adhesive (OCA) layer on the glass. The remaining samples had optically clear adhesive layers applied to one side of the glass. The sharp indenter was pushed against the glass surface on which the optically clear adhesive layer was not applied. For all the samples, the plot shows that the larger the contact force on the glass surface, the higher the stress in the glass. Therefore, the contact force between the glass and the hard surface can be used as a surrogate for glass stress, which is hard to obtain either from test or simulation, during sharp contact. Based on the results of the static indentation study, the value of contact force was chosen as the criteria for comparing glass reliability performance.

FIG. 6A shows a test model 50 used to simulate the contact force between a cover glass and a hard surface in a device drop test. The test model includes, in order, a cover glass 52, an energy absorbing interlayer 54, a display panel 56, a carrier body 58, a weight 60 to represent a battery, and a back cover 62. The back cover 62 and the carrier body 58 will be connected together by a set of screws 64. The test model 50 is constructed to have similar dynamic behavior to a real handheld device in a device drop test.

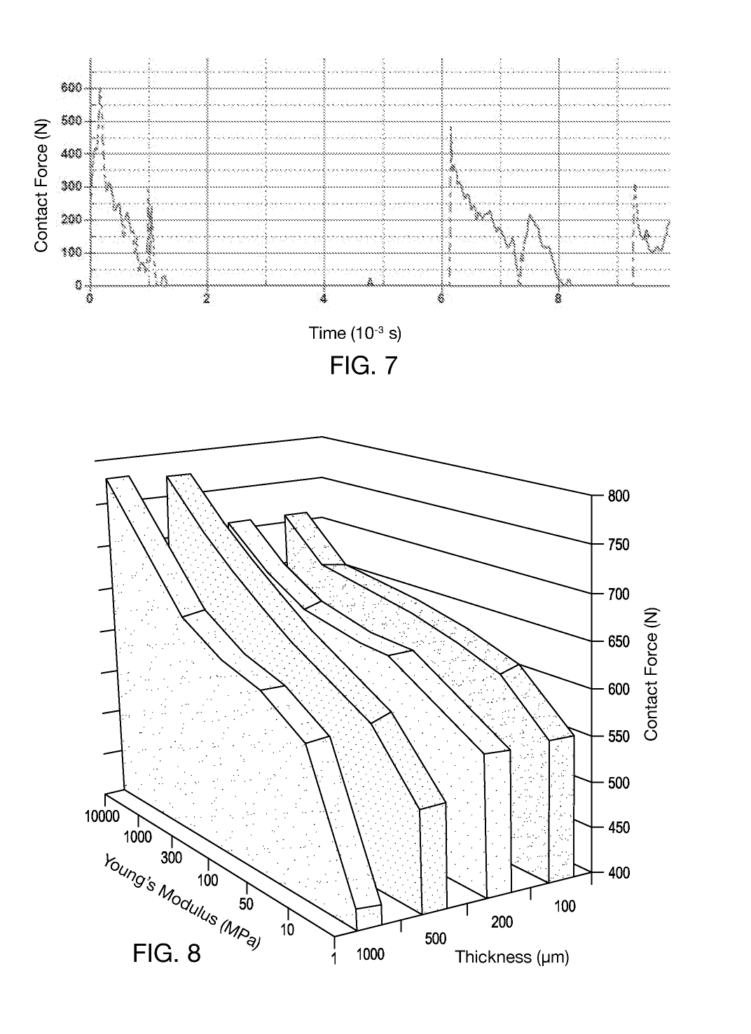

FIG. 6B shows a setup of the test model 50 to simulate the drop test. The test model 50 touches the hard surface 70 at a certain angle and the cover glass is in contact with the hard surface 70, as shown, for example, at 72. The corners and edges of the cover glass will touch the hard surface 70 multiple times depending on the drop orientation. The contact force between the cover glass of the test model 50 and the hard surface 72 is simulated using finite element analysis. The finite element model generates the time history of the contact force on the cover glass and is shown in FIG. 7. As can be seen in FIG. 7, the contact force reaches peaks as the corners of the test model 50 touch the hard surface 70. By varying the thickness and the modulus of the soft interlayer of the test model 50, the dependency of the contact on these parameters, which all contribute to the rigidity of the soft interlayer, can be determined.

FIG. 8 shows the dependency of the maximum contact force on the interlayer modulus (E) and thickness. From the response surface plot, it is possible to see that the existence of an energy absorbing interlayer makes a significant difference in the contact force. The thicker and softer the interlayer is, the lower the contact force. Therefore, there are two parameters to play with to reduce the contact force, by either reducing the modulus or increasing the thickness of the interlayer. In handheld device design, an appropriate combination of the soft interlayer thickness and modulus to obtain reasonable reliability performance of the cover glass can be obtained while satisfying the aesthetic and functional design needs.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1. A portable electronic device, comprising:
a device body having contained in a cavity therein a plurality of device structures, one of the device structures being a display module;
a cover glass disposed at an opening of the device body such that at least one of the plurality of device structures underlies the cover glass; and
an energy absorbing interlayer disposed between the cover glass and at least one underlying device structure, the energy absorbing interlayer having a stiffness that is lower than a stiffness of the cover glass.

2. The portable electronic device of claim 1, wherein the stiffness of the energy absorbing interlayer is lower than a stiffness of the at least one underlying device structure.

3. The portable electronic device of claim 1, wherein the at least one underlying device structure is the display module.

4. The portable electronic device of claim 1, wherein the at least one underlying device structure is a bezel arranged to couple the cover glass to the device body.

5. The portable electronic device of claim 4, wherein the energy absorbing interlayer has a loop shape.

6. The portable electronic device of claim 1, wherein the energy absorbing interlayer comprises at least one polymer.

7. The portable electronic device of claim 1, wherein the energy absorbing interlayer comprises an optically clear adhesive made of at least one polymer.

8. The portable electronic device of claim 1, wherein the energy absorbing interlayer is formed on a surface of the cover glass.

9. The portable electronic device of claim 1, wherein a Young's modulus of the energy absorbing interlayer is at least 10 times smaller than a Young's modulus of the cover glass.

10. The portable electronic device of claim 1, wherein a Young's modulus of the energy absorbing interlayer is in a range from 1 MPa to 100 MPa.

11. The portable electronic device of claim 1, wherein a layer thickness of the energy absorbing interlayer is in a range from 100 μm to 2.5 mm.

12. The portable electronic device of claim 1, wherein the cover glass is made of a glass or glass-ceramic material having at least one surface under a compressive stress of at least 200 MPa and a compressively stressed layer having a depth of at least 1% of a thickness of the glass or glass-ceramic material.

13. The portable electronic device of claim 1, wherein a corner area of the energy absorbing interlayer is thicker than a non-corner area of the energy absorbing interlayer.

14. The portable electronic device of claim 1, wherein an edge area of the energy absorbing interlayer is thicker than a non-edge area of the energy absorbing interlayer.

15. A cover glass article for a portable electronic device, comprising:
a cover glass shaped to at least partially cover an opening of a device body of the portable electronic device, the cover glass being made of a glass or glass-ceramic material having at least one surface under a compressive stress of at least 200 MPa and a compressively stressed layer with a depth of layer of at least 1% of a thickness of the material; and
an energy absorbing layer formed on a surface of the cover glass, the energy absorbing layer having a stiffness lower than a stiffness of the cover glass.

16. The cover glass article of claim 15, wherein the energy absorbing layer comprises at least one polymer.

17. The cover glass article of claim 15, wherein the energy absorbing layer comprises an optically clear adhesive made of at least one polymer.

18. The cover glass article of claim 15, wherein a Young's modulus of the energy absorbing layer is at least 10 times smaller than the elastic modulus of the cover glass.

19. The cover glass article of claim 15, wherein a layer thickness of the energy absorbing layer is in a range from 100 μm to 2.5 mm.

20. The cover glass article of claim 15, wherein the thickness of the cover glass in a range from 50 μm to 2.0 mm.

21. The cover glass article of claim 15, wherein the energy absorbing layer is provided as a sheet of material or as strips of material or as a loop of material.

22. The cover glass article of claim 15, wherein the cover glass is transparent.

23. The cover glass article of claim 15, wherein the energy absorbing layer is transparent.

24. The cover glass article of claim 15, wherein the energy absorbing layer has a non-uniform thickness.

25. The cover glass article of claim 24, wherein a portion of the energy absorbing layer corresponding to a corner area of the cover glass is at least 1.5 times thicker than a portion of the energy absorbing layer corresponding to a non-corner area of the cover glass.

26. The cover glass article of claim 24, wherein a portion of the energy absorbing layer corresponding to an edge area of the cover glass is at least 1.5 times thicker than a portion of the energy absorbing layer corresponding to a non-edge area of the cover glass.
